(19) United States
(12) Patent Application Publication
(10) Pub. No.: US 2023/0029936 A1
(43) Pub. Date: Feb. 2, 2023

(54) SEMICONDUCTOR STRUCTURE, STORAGE STRUCTURE AND METHOD FOR FABRICATING SAME

(71) Applicant: CHANGXIN MEMORY TECHNOLOGIES, INC., Hefei (CN)

(72) Inventor: Guangsu SHAO, Hefei (CN)

(21) Appl. No.: 17/952,264

(22) Filed: Sep. 25, 2022

(30) Foreign Application Priority Data
Jun. 23, 2022 (CN) 202210719936.4

(51) Int. Cl. H01L 27/108

(52) U.S. Cl. CPC H01L 27/10814; H01L 27/10891; H01L 27/10885; H01L 27/1085

(57) ABSTRACT

Embodiments relate to a semiconductor structure and a method for fabricating the same. The method includes: providing a substrate; forming a first isolation trench in the substrate; filling a first isolation dielectric layer in the first isolation trench; forming a second isolation trench; forming a second isolation dielectric layer in the second isolation trench; forming word line structures arranged at intervals, where the word line structures extend along the second direction to wrap the channel regions of the active pillars in a same row; etching back the second isolation dielectric layer and the first isolation dielectric layer to expose second connection terminals of the active pillars; and forming a protective layer configured to define positions of the word line structures and wrap the second connection terminals of the active pillars.

### CROSS-REFERENCE TO RELATED APPLICATION

This application claims priority to Chinese Patent Application No. 202210719936.4, titled “SEMICONDUCTOR STRUCTURE, STORAGE STRUCTURE AND METHOD FOR FABRICATING SAME” and filed to the State Patent Intellectual Property Office on Jun. 23, 2022, the entire contents of which are incorporated herein by reference.

### TECHNICAL FIELD

The present disclosure relates to the field of semiconductor fabrication technology, and more particularly, to a semiconductor structure, a storage structure, and a method for fabricating the same.

### BACKGROUND

With the rapid development of semiconductor fabrication technologies, semiconductor devices are developing toward a direction of higher component density and higher integration level, and a development trend of semiconductor process nodes following the Moore's Law is decreasing. As the most basic semiconductor devices, transistors are widely used at present. Therefore, with the increase in the component density and integration level of semiconductor devices, to adapt to the decrease of the process nodes, lengths of channels of the transistors need to be continuously shortened.

With the shortening of the lengths of the channels, pitches between sources and drains of the transistors are also shortened, and control capability of gates to the channels becomes worse, such that short-channel effects (SCEs) are more likely to occur, and leakage currents in the channels of the transistors are increased. Therefore, to further improve the control of the channels and reduce the SCEs, the transistors having vertical gate-all-around (VGAA) structures are developed, and accordingly, the transistors are also called VGAA transistors. In the VGAA transistors, gate dielectrics and gate electrodes completely surround channel regions. This configuration achieves good control of the channels and reduces the SCEs.

At present, when fabricating the VGAA transistors, sizes of bit line shallow trench isolation spaces (BL STI Spaces) and sizes of word line shallow trench isolation spaces (WL STI Spaces) are basically the same, which leaves less space for word lines in subsequent processes.

### SUMMARY

On this basis, it is necessary to provide, for the above defects in the prior art, a semiconductor structure, a storage structure, and method for fabricating the same.

The present disclosure provides a method for fabricating a semiconductor structure, including: providing a substrate; etching the substrate to form a first isolation trench in the substrate, where the first isolation trench extends along a first direction; filling a first isolation dielectric layer in the first isolation trench; etching the substrate and the first isolation dielectric layer to form a second isolation trench, where the second isolation trench extends along a second direction, the first direction intersects with the second direction, the second isolation trench and the first isolation trench are configured to jointly isolate a plurality of active pillars, a width of the second isolation trench is greater than a width of the first isolation trench, and each of the plurality of active pillars includes a first connection terminal, a second connection terminal, and a channel region positioned between the first connection terminal and the second connection terminal; forming a second isolation dielectric layer in the second isolation trench; forming a plurality of word line structures arranged at intervals, where the plurality of word line structures all extend along the second direction to wrap the channel regions of the plurality of active pillars positioned in a same row; etching back the second isolation dielectric layer and the first isolation dielectric layer to expose the second connection terminal of each of the plurality of active pillars; and forming a protective layer, where the protective layer is configured to define positions of the plurality of word line structures and wrap the second connection terminal of each of the plurality of active pillars.

According to some embodiments, the present disclosure also provides a semiconductor structure, including: a substrate, where the substrate is internally provided with a first isolation trench and a second isolation trench, and the first isolation trench and the second isolation trench are configured to isolate a plurality of active pillars arranged at intervals; the first isolation trench extends along a first direction, the second isolation trench extends along a second direction, and the first direction intersects with the second direction; a width of the second isolation trench is greater than that of the first isolation trench; and each of the plurality of active pillars includes a first connection terminal, a second connection terminal, and a channel region positioned between the first connection terminal and the second connection terminal; a first isolation dielectric layer positioned in the first isolation trench; a second isolation dielectric layer positioned in the second isolation trench, where the second isolation dielectric layer and the first isolation dielectric layer are configured to jointly wrap the first connection terminal of each of the plurality of active pillars, and the second isolation dielectric layer and the first isolation dielectric layer expose the second connection terminal; a plurality of word line structures arranged at intervals, where the plurality of word line structures all extend along the second direction to wrap the channel regions of the plurality of active pillars positioned in a same row; and a protective layer, where the protective layer surrounds the second connection terminal of each of the plurality of active pillars.

According to some embodiments, the present disclosure also provides a method for fabricating a storage structure, including: fabricating the semiconductor structure by means of the method for fabricating the semiconductor structure provided in any one of the foregoing embodiments; forming a plurality of storage node structures, where the plurality of storage node structures are positioned above the second connection terminals of the plurality of active pillars, and are connected in one-to-one correspondence to the second connection terminals; and forming a plurality of capacitors, where the plurality of capacitors are positioned on upper surfaces of the plurality of storage node structures, and are arranged in one-to-one correspondence with the plurality of storage node structures.

According to some embodiments, the present disclosure also provides a storage structure, including: the semiconductor structure provided in any one of the foregoing embodiments; a plurality of storage node structures, where the plurality of storage node structures are positioned above the second connection terminals of the plurality of active pillars, and are connected in one-to-one correspondence to the second connection terminals; and a plurality of capacitors, where the plurality of capacitors are positioned on upper surfaces of the plurality of storage node structures, and are arranged in one-to-one correspondence with the plurality of storage node structures.

### BRIEF DESCRIPTION OF THE DRAWINGS

To describe the technical solutions in the embodiments of the present disclosure or the existing technologies more clearly, the accompanying drawings required for describing the embodiments or the existing technologies will be briefly introduced below. Apparently, the accompanying drawings in the following description are merely some embodiments of the present disclosure. To those of ordinary skills in the art, other accompanying drawings may also be derived from these accompanying drawings without creative efforts.

FIG. 1 is a flowchart of a method for fabricating a semiconductor structure according to an embodiment of the present disclosure;

FIG. 2 is a schematic diagram showing aa′ direction, bb′ direction, cc′ direction and dd′ direction according to an embodiment of the present disclosure;

FIG. 3(a) is a schematic cross-sectional structural diagram of a structure obtained in Step S1 in the aa′ direction according to an embodiment of the present disclosure, FIG. 3(b) is a schematic cross-sectional structural diagram of the structure obtained in Step S1 in the bb′ direction according to an embodiment of the present disclosure, FIG. 3(c) is a schematic cross-sectional structural diagram of the structure obtained in Step S1 in the cc′ direction according to an embodiment of the present disclosure, and FIG. 3(d) is a schematic cross-sectional structural diagram of the structure obtained in Step S1 in the dd′ direction according to an embodiment of the present disclosure;

FIG. 4(a) is a schematic cross-sectional structural diagram of a structure obtained in Step S2 in the aa′ direction according to an embodiment of the present disclosure, FIG. 4(b) is a schematic cross-sectional structural diagram of the structure obtained in Step S2 in the bb′ direction according to an embodiment of the present disclosure, FIG. 4(c) is a schematic cross-sectional structural diagram of the structure obtained in Step S2 in the cc′ direction according to an embodiment of the present disclosure, and FIG. 4(d) is a schematic cross-sectional structural diagram of the structure obtained in Step S2 in the dd′ direction according to an embodiment of the present disclosure;

FIG. 5(a) is a schematic cross-sectional structural diagram of a structure obtained in Step S3 in the aa′ direction according to an embodiment of the present disclosure, FIG. 5(b) is a schematic cross-sectional structural diagram of the structure obtained in Step S3 in the bb′ direction according to an embodiment of the present disclosure, FIG. 5(c) is a schematic cross-sectional structural diagram of the structure obtained in Step S3 in the cc′ direction according to an embodiment of the present disclosure, and FIG. 5(d) is a schematic cross-sectional structural diagram of the structure obtained in Step S3 in the dd′ direction according to an embodiment of the present disclosure;

FIG. 6(a) is a schematic cross-sectional structural diagram of a structure obtained in Step S4 in the aa′ direction according to an embodiment of the present disclosure, FIG. 6(b) is a schematic cross-sectional structural diagram of the structure obtained in Step S4 in the bb′ direction according to an embodiment of the present disclosure, FIG. 6(c) is a schematic cross-sectional structural diagram of the structure obtained in Step S4 in the cc′ direction according to an embodiment of the present disclosure, and FIG. 6(d) is a schematic cross-sectional structural diagram of the structure obtained in Step S4 in the dd′ direction according to an embodiment of the present disclosure;

FIG. 7(a) is a schematic cross-sectional structural diagram of a structure obtained in the aa′ direction after sidewall oxide layers are formed according to an embodiment of the present disclosure, FIG. 7(b) is a schematic cross-sectional structural diagram of the structure obtained in the bb′ direction after the sidewall oxide layers are formed according to an embodiment of the present disclosure, FIG. 7(c) is a schematic cross-sectional structural diagram of the structure obtained in the cc′ direction after the sidewall oxide layers are formed according to an embodiment of the present disclosure, and FIG. 7(d) is a schematic cross-sectional structural diagram of the structure obtained in the dd′ direction after the sidewall oxide layers are formed according to an embodiment of the present disclosure;

FIG. 8(a) is a schematic cross-sectional structural diagram of a structure obtained in the aa′ direction after bit line shallow trench isolation spaces (BL STI Spaces) are formed according to an embodiment of the present disclosure, FIG. 8(b) is a schematic cross-sectional structural diagram of the structure obtained in the bb′ direction after the BL STI Spaces are formed according to an embodiment of the present disclosure, FIG. 8(c) is a schematic cross-sectional structural diagram of the structure obtained in the cc′ direction after the BL STI Spaces are formed according to an embodiment of the present disclosure, and FIG. 8(d) is a schematic cross-sectional structural diagram of the structure obtained in the dd′ direction after the BL STI Spaces are formed according to an embodiment of the present disclosure;

FIG. 9(a) is a schematic cross-sectional structural diagram of a structure obtained in the aa′ direction after first metal silicide layers are formed according to an embodiment of the present disclosure, FIG. 9(b) is a schematic cross-sectional structural diagram of the structure obtained in the bb′ direction after the first metal silicide layers are formed according to an embodiment of the present disclosure, FIG. 9(c) is a schematic cross-sectional structural diagram of the structure obtained in the cc′ direction after the first metal silicide layers are formed according to an embodiment of the present disclosure, and FIG. 9(d) is a schematic cross-sectional structural diagram of the structure obtained in the dd′ direction after the first metal silicide layers are formed according to an embodiment of the present disclosure;

FIG. 10(a) is a schematic cross-sectional structural diagram of a structure obtained in the aa′ direction after bit lines are formed according to an embodiment of the present disclosure, FIG. 10(b) is a schematic cross-sectional structural diagram of the structure obtained in the bb′ direction after the bit lines are formed according to an embodiment of the present disclosure, FIG. 10(c) is a schematic cross-sectional structural diagram of the structure obtained in the cc′ direction after the bit lines are formed according to an embodiment of the present disclosure, and FIG. 10(d) is a schematic cross-sectional structural diagram of the structure obtained in the dd′ direction after the bit lines are formed according to an embodiment of the present disclosure;

FIG. 11(a) is a schematic cross-sectional structural diagram of a structure obtained in Step S5 in the aa′ direction according to an embodiment of the present disclosure, FIG. 11(b) is a schematic cross-sectional structural diagram of the structure obtained in Step S5 in the bb′ direction according to an embodiment of the present disclosure, FIG. 11(c) is a schematic cross-sectional structural diagram of the structure obtained in Step S5 in the cc′ direction according to an embodiment of the present disclosure, and FIG. 11(d) is a schematic cross-sectional structural diagram of the structure obtained in Step S5 in the dd′ direction according to an embodiment of the present disclosure;

FIG. 12 is a flowchart of Step S6 according to an embodiment of the present disclosure;

FIG. 13(a) is a schematic cross-sectional structural diagram of a structure obtained in Step S601 in the aa′ direction according to an embodiment of the present disclosure, FIG. 13(b) is a schematic cross-sectional structural diagram of the structure obtained in Step S601 in the bb′ direction according to an embodiment of the present disclosure, FIG. 13(c) is a schematic cross-sectional structural diagram of the structure obtained in Step S601 in the cc′ direction according to an embodiment of the present disclosure, and FIG. 13(d) is a schematic cross-sectional structural diagram of the structure obtained in Step S601 in the dd′ direction according to an embodiment of the present disclosure;

FIG. 14(a) is a schematic cross-sectional structural diagram of a structure obtained in the aa′ direction after patterned mask layers are formed according to an embodiment of the present disclosure, FIG. 14(b) is a schematic cross-sectional structural diagram of the structure obtained in the bb′ direction after the patterned mask layers are formed according to an embodiment of the present disclosure, FIG. 14(c) is a schematic cross-sectional structural diagram of the structure obtained in the cc′ direction after the patterned mask layers are formed according to an embodiment of the present disclosure, and FIG. 14(d) is a schematic cross-sectional structural diagram of the structure obtained in the dd′ direction after the patterned mask layers are formed according to an embodiment of the present disclosure;

FIG. 15(a) is a schematic cross-sectional structural diagram of a structure obtained in the aa′ direction after spacers are formed according to an embodiment of the present disclosure, FIG. 15(b) is a schematic cross-sectional structural diagram of the structure obtained in the bb′ direction after the spacers are formed according to an embodiment of the present disclosure, FIG. 15(c) is a schematic cross-sectional structural diagram of the structure obtained in the cc′ direction after the spacers are formed according to an embodiment of the present disclosure, and FIG. 15(d) is a schematic cross-sectional structural diagram of the structure obtained in the dd′ direction after the spacers are formed according to an embodiment of the present disclosure;

FIG. 16 is a flowchart of the method for fabricating the semiconductor structure after protective layers are formed according to an embodiment of the present disclosure;

FIG. 17(a) is a schematic cross-sectional structural diagram of a structure obtained in Step S702 in the aa′ direction according to an embodiment of the present disclosure, FIG. 17(b) is a schematic cross-sectional structural diagram of the structure obtained in Step S702 in the bb′ direction according to an embodiment of the present disclosure, FIG. 17(c) is a schematic cross-sectional structural diagram of the structure obtained in Step S702 in the cc′ direction according to an embodiment of the present disclosure, and FIG. 17(d) is a schematic cross-sectional structural diagram of the structure obtained in Step S702 in the dd′ direction according to an embodiment of the present disclosure;

FIG. 18(a) is a schematic cross-sectional structural diagram of a structure obtained in the aa′ direction after word line conductive material layers are formed according to an embodiment of the present disclosure, FIG. 18(b) is a schematic cross-sectional structural diagram of the structure obtained in the bb′ direction after the word line conductive material layers are formed according to an embodiment of the present disclosure, FIG. 18(c) is a schematic cross-sectional structural diagram of the structure obtained in the cc′ direction after the word line conductive material layers are formed according to an embodiment of the present disclosure, and FIG. 18(d) is a schematic cross-sectional structural diagram of the structure obtained in the dd′ direction after the word line conductive material layers are formed according to an embodiment of the present disclosure;

FIG. 19(a) is a schematic cross-sectional structural diagram of a structure obtained in the aa′ direction after performing first etchback on the word line conductive material layer according to an embodiment of the present disclosure, FIG. 19(b) is a schematic cross-sectional structural diagram of the structure obtained in the bb′ direction after performing the first etchback on the word line conductive material layer according to an embodiment of the present disclosure, FIG. 19(c) is a schematic cross-sectional structural diagram of the structure obtained in the cc′ direction after performing the first etchback on the word line conductive material layer according to an embodiment of the present disclosure, and FIG. 19(d) is a schematic cross-sectional structural diagram of the structure obtained in the dd′ direction after performing the first etchback on the word line conductive material layer according to an embodiment of the present disclosure;

FIG. 20(a) is a schematic cross-sectional structural diagram of a structure obtained in the aa′ direction after word line conductive layers are formed according to an embodiment of the present disclosure, FIG. 20(b) is a schematic cross-sectional structural diagram of the structure obtained in the bb′ direction after the word line conductive layers are formed according to an embodiment of the present disclosure, FIG. 20(c) is a schematic cross-sectional structural diagram of the structure obtained in the cc′ direction after the word line conductive layers are formed according to an embodiment of the present disclosure, and FIG. 20(d) is a schematic cross-sectional structural diagram of the structure obtained in the dd′ direction after the word line conductive layers are formed according to an embodiment of the present disclosure;

FIG. 21(a) is a schematic cross-sectional structural diagram of a structure obtained in the aa′ direction after filling dielectric layers are formed according to an embodiment of the present disclosure, FIG. 21(b) is a schematic cross-sectional structural diagram of the structure obtained in the bb′ direction after the filling dielectric layers are formed according to an embodiment of the present disclosure, FIG. 21(c) is a schematic cross-sectional structural diagram of the structure obtained in the cc′ direction after the filling dielectric layers are formed according to an embodiment of the present disclosure, and FIG. 21(d) is a schematic cross-sectional structural diagram of the structure obtained in the dd′ direction after the filling dielectric layers are formed according to an embodiment of the present disclosure; FIG. 21(a) is also a schematic cross-sectional structural diagram of the semiconductor structure in the aa′ direction according to an embodiment of the present disclosure, FIG. 21(b) is also a schematic cross-sectional structural diagram of the semiconductor structure in the bb′ direction according to an embodiment of the present disclosure, FIG. 21(c) is also a schematic cross-sectional structural diagram of the semiconductor structure in the cc′ direction according to an embodiment of the present disclosure, and FIG. 21(d) is also a schematic cross-sectional structural diagram of the semiconductor structure in the dd′ direction according to an embodiment of the present disclosure;

FIG. 22 is a flowchart of a method for fabricating a storage structure according to an embodiment of the present disclosure;

FIG. 23(a) is a schematic cross-sectional structural diagram of a structure obtained in the aa′ direction after removing the patterned mask layers according to an embodiment of the present disclosure, FIG. 23(b) is a schematic cross-sectional structural diagram of the structure obtained in the bb′ direction after removing the patterned mask layers according to an embodiment of the present disclosure, FIG. 23(c) is a schematic cross-sectional structural diagram of the structure obtained in the cc′ direction after removing the patterned mask layers according to an embodiment of the present disclosure, and FIG. 23(d) is a schematic cross-sectional structural diagram of the structure obtained in the dd′ direction after removing the patterned mask layers according to an embodiment of the present disclosure;

FIG. 24(a) is a schematic cross-sectional structural diagram of a structure obtained in the aa′ direction after metal silicides are formed according to an embodiment of the present disclosure, FIG. 24(b) is a schematic cross-sectional structural diagram of the structure obtained in the bb′ direction after the metal silicides are formed according to an embodiment of the present disclosure, FIG. 24(c) is a schematic cross-sectional structural diagram of the structure obtained in the cc′ direction after the metal silicides are formed according to an embodiment of the present disclosure, and FIG. 24(d) is a schematic cross-sectional structural diagram of the structure obtained in the dd′ direction after the metal silicides are formed according to an embodiment of the present disclosure;

FIG. 25(a) is a schematic cross-sectional structural diagram of a structure obtained in Step S222 in the aa′ direction according to an embodiment of the present disclosure, FIG. 25(b) is a schematic cross-sectional structural diagram of the structure obtained in Step S222 in the bb′ direction according to an embodiment of the present disclosure, FIG. 25(c) is a schematic cross-sectional structural diagram of the structure obtained in Step S222 in the cc′ direction according to an embodiment of the present disclosure, and FIG. 25(d) is a schematic cross-sectional structural diagram of the structure obtained in Step S222 in the dd′ direction according to an embodiment of the present disclosure; and

FIG. 26(a) is a schematic cross-sectional structural diagram of a structure obtained in Step S223 in the aa′ direction according to an embodiment of the present disclosure, FIG. 26(b) is a schematic cross-sectional structural diagram of the structure obtained in Step S223 in the bb′ direction according to an embodiment of the present disclosure, FIG. 26(c) is a schematic cross-sectional structural diagram of the structure obtained in Step S223 in the cc′ direction according to an embodiment of the present disclosure, and FIG. 26(d) is a schematic cross-sectional structural diagram of the structure obtained in Step S223 in the dd′ direction according to an embodiment of the present disclosure; FIG. 26(a) is also a schematic cross-sectional structural diagram of the storage structure in the aa′ direction according to an embodiment of the present disclosure, FIG. 26(b) is also a schematic cross-sectional structural diagram of the storage structure in the bb′ direction according to an embodiment of the present disclosure, FIG. 26(c) is also a schematic cross-sectional structural diagram of the storage structure in the cc′ direction according to an embodiment of the present disclosure, and FIG. 26(d) is also a schematic cross-sectional structural diagram of the storage structure in the dd′ direction according to an embodiment of the present disclosure.

### REFERENCE NUMERALS IN THE ACCOMPANYING DRAWINGS

1—substrate; 10—active pillar; 10b—second connection terminal; 10c—channel region; 101—first isolation trench; 102—first isolation dielectric layer; 103—second isolation trench; 104—bit line shallow trench isolation space (BL STI Space); 105—second isolation dielectric layer; 106—protective layer; 107—sidewall oxide layer; 108—first metal silicide layer; 109—bit line; 11—word line structure; 110—patterned mask layer; 111—spacer; 112—gate dielectric layer; 113—word line conductive layer; 114—word line conductive material layer; 115—filling dielectric layer; 116—spacer material layer; 201—metal silicide layer; 2—storage node structure; and 3—capacitor.

### DETAILED DESCRIPTION

For ease of understanding the present disclosure, the present disclosure will be described more fully hereinafter with reference to the accompanying drawings. Some embodiments of the present disclosure are provided in the accompanying drawings. The present disclosure may, however, be embodied in many different forms and should not be limited to the embodiments set forth herein. Rather, these embodiments are provided such that the present disclosure will be more thorough and complete.

Unless otherwise defined, all technical and scientific terms employed herein have the same meaning as commonly understood by one of ordinary skill in the art to which the present disclosure belongs. The terms employed in the specification of the present disclosure are merely for the purpose of describing some embodiments and are not intended for limiting the present disclosure.

It should be understood that when an element or layer is referred to as being “on” other elements or layers, it may be directly on, adjacent to, connected or coupled to the other elements or layers, or intervening elements or layers may be present. It should be understood that although the terms first, second, etc. may be employed to describe various elements, components, regions, layers, doping types and/or sections, these elements, components, regions, layers, doping types and/or sections should not be limited by these terms. These terms are only employed to distinguish one element, component, region, layer, doping type, or section from another element, component, region, layer, doping type, or section. Thus, without departing from the teachings of the present disclosure, a first element, component, region, layer, doping type or portion discussed below may be represented as a second element, component, region, layer or portion. For example, a first isolation dielectric layer may be termed a second isolation dielectric layer, and similarly, the second isolation dielectric layer may be termed the first isolation dielectric layer. Furthermore, the first isolation dielectric layer and the second isolation dielectric layer may be different isolation dielectric layers.

Spatially relative terms, such as “below”, “above” and the like, may be used herein to describe the relationship between one element or feature to another element(s) or feature(s) as illustrated in the figures. It should be understood that the spatially relative terms may be intended to encompass different orientations of a device in use or operation in addition to the orientation depicted in the figures. For example, if the device in the figures is turned over, elements described as “below” other elements or features would then be oriented “above” the other elements or features. Thus, the exemplary terms “below” and “above” can encompass both an orientation of above and below. In addition, the device may also be otherwise oriented (for example, rotated 90 degrees or at other orientations) and the spatially descriptors used herein should be interpreted accordingly.

As used herein, the singular forms of “a”, “one” and “said/the” are also intended to include plural forms, unless the context clearly indicates otherwise. It should also be understood that the terms “comprising” and/or “including”, when used in this specification, may determine the presence of the described features, integers, steps, operations, elements and/or components, but do not preclude the presence or addition of one or more other features, integers, steps, operations, elements, components, and/or groups thereof.

Embodiments of the present disclosure are described herein with reference to cross-sectional illustrations serving as schematic illustrations of idealized embodiments (and intermediate structures) of the present disclosure. As such, variations from the shapes of the illustrations as a result, for example, of manufacturing techniques and/or tolerances, may be expected. Thus, embodiments of the present disclosure should not be construed as being limited to particular shapes of regions illustrated herein but may include deviations in shapes that result, for example, from fabrication technologies. Thus, regions illustrated in the figures are schematic in nature and their shapes do not necessarily illustrate the actual shape of a region of the device and do not limit the scope of the present disclosure.

According to some embodiments, the present disclosure provides a semiconductor structure, a storage structure and a method for fabricating the same.

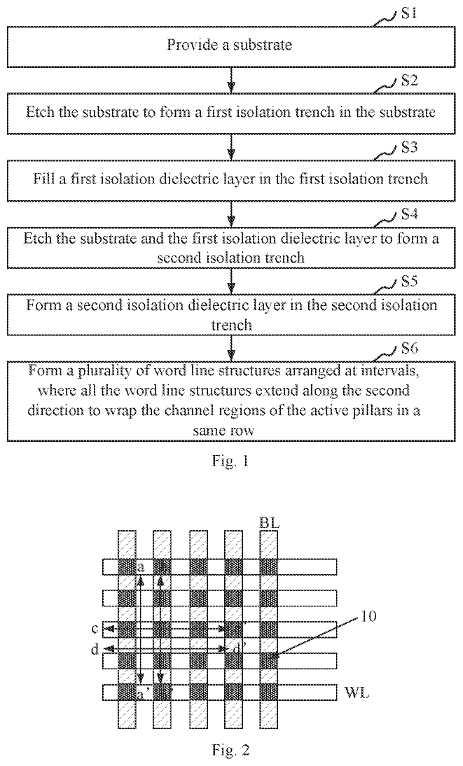

Referring to FIG. 1, according to an embodiment of the present disclosure, a method for fabricating the semiconductor structure may include following steps.

The method for fabricating the semiconductor structure includes following steps.

S1: providing a substrate.

S2: etching the substrate to form a first isolation trench in the substrate.

In some embodiments, the first isolation trench may extend along a first direction.

S3: filling a first isolation dielectric layer in the first isolation trench.

S4: etching the substrate and the first isolation dielectric layer to form a second isolation trench.

In some embodiments, the second isolation trench may extend along a second direction, and the first direction intersects with the second direction.

After the second isolation trench is formed, the second isolation trench and the first isolation trench can jointly isolate a plurality of active pillars. Each of the active pillars includes a first connection terminal, a second connection terminal, and a channel region positioned between the first connection terminal and the second connection terminal. It should be noted that in the present disclosure, a width of the second isolation trench should be greater than that of the first isolation trench.

S5: forming a second isolation dielectric layer in the second isolation trench.

S6: forming a plurality of word line structures arranged at intervals, where the plurality of word line structures all extend along the second direction to wrap the channel regions of the active pillars positioned in a same row.

In the method for fabricating the semiconductor structure provided by the above embodiment, by forming the second isolation trenches wider than the first isolation trenches, larger space is provided for subsequent formation of word line structures. Furthermore, protection may also be provided for sources/drains formed subsequently.

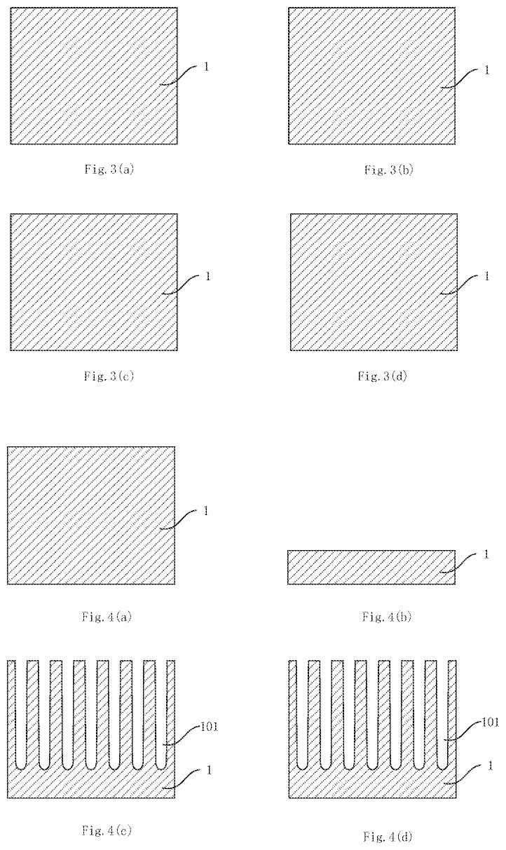

Referring to FIGS. 2 to 3, in Step S1, a substrate 1 is provided.

FIG. 2 shows aa′ direction, bb′ direction, cc′ direction and dd′ direction according the present disclosure.

FIG. 3(a) shows a schematic cross-sectional structural diagram of a structure obtained in Step S1 in the aa′ direction, FIG. 3(b) shows a schematic cross-sectional structural diagram of the structure obtained in Step S1 in the bb′ direction, FIG. 3(c) shows a schematic cross-sectional structural diagram of the structure obtained in Step S1 in the cc′ direction, and FIG. 3(d) shows a schematic cross-sectional structural diagram of the structure obtained in Step S1 in the dd′ direction.

In the embodiments of the present disclosure, no limitation is imposed on a material of the substrate 1. As an example, the substrate 1 may include, but is not limited to, any one or more of a silicon substrate, a sapphire substrate, a glass substrate, a silicon carbide substrate, a gallium nitride substrate, or a gallium arsenide substrate, etc.

Referring to FIG. 4, in Step S2, the substrate 1 is etched to form a first isolation trench 101 in the substrate 1.

FIG. 4(a) shows a schematic cross-sectional structural diagram of a structure obtained in Step S2 in the aa′ direction, FIG. 4(b) shows a schematic cross-sectional structural diagram of the structure obtained in Step S2 in the bb′ direction, FIG. 4(c) shows a schematic cross-sectional structural diagram of the structure obtained in Step S2 in the cc′ direction, and FIG. 4(d) shows a schematic cross-sectional structural diagram of the structure obtained in Step S2 in the dd′ direction.

In some embodiments, the first isolation trench 101 may extend along the first direction.

In the present disclosure, the first direction may refer to a direction shown in the aa′ direction or the bb′ direction.

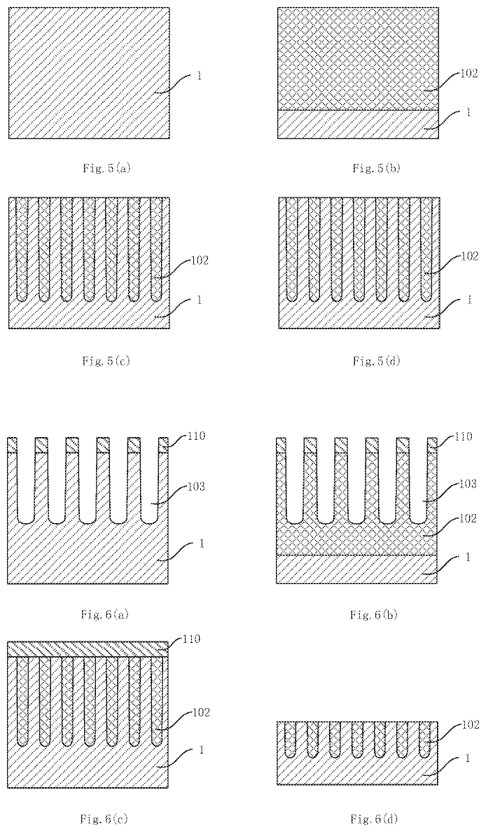

Referring to FIG. 5, in Step S3, a first isolation dielectric layer 102 is filled in the first isolation trench 101.

FIG. 5(a) shows a schematic cross-sectional structural diagram of a structure obtained in Step S3 in the aa′ direction, FIG. 5(b) shows a schematic cross-sectional structural diagram of the structure obtained in Step S3 in the bb′ direction, FIG. 5(c) shows a schematic cross-sectional structural diagram of the structure obtained in Step S3 in the cc′ direction, and FIG. 5(d) shows a schematic cross-sectional structural diagram of the structure obtained in Step S3 in the dd′ direction.

Referring to FIG. 6, in Step S4, the substrate 1 and the first isolation dielectric layer 102 are etched to form a second isolation trench 103. A width of the second isolation trench 103 is greater than that of the first isolation trench 101.

FIG. 6(a) shows a schematic cross-sectional structural diagram of a structure obtained in Step S4 in the aa′ direction, FIG. 6(b) shows a schematic cross-sectional structural diagram of the structure obtained in Step S4 in the bb′ direction, FIG. 6(c) shows a schematic cross-sectional structural diagram of the structure obtained in Step S4 in the cc′ direction, and FIG. 6(d) shows a schematic cross-sectional structural diagram of the structure obtained in Step S4 in the dd′ direction.

In some embodiments, the second isolation trench 103 extends along the second direction. In the present disclosure, the first direction intersects the second direction. As an example, the second direction may refer to a direction as shown in the cc′ direction or the dd′ direction.

As shown in FIG. 2, the second isolation trench 103 and the first isolation trench 101 can jointly isolate a plurality of active pillars 10. Each of the active pillars 10 may include a first connection terminal, a second connection terminal, and a channel region between the first connection terminal and the second connection terminal.

The present disclosure does not limit the widths of the second isolation trenches 103 and the widths of the first isolation trenches 101, as long as the widths of the second isolation trenches 103 are greater than the widths of the first isolation trenches 101. As an example, the widths of the second isolation trenches 103 may be 1.2 times to 1.8 times the widths of the first isolation trenches 101. For example, the widths of the second isolation trenches 103 may be 1.2 times, 1.4 times, 1.6 times or 1.8 times the widths of the first isolation trenches 101.

In some embodiments of the present disclosure, before forming second isolation dielectric layers 105 in the second isolation trenches 103, the step of forming a plurality of bit lines arranged at intervals in a substrate 1 may also be included.

In some embodiments, the plurality of bit lines arranged at intervals are positioned below active pillars 10; and each of the bit lines may extend along a first direction, to sequentially connect in series first connection terminals of the active pillars 10 positioned in a same column.

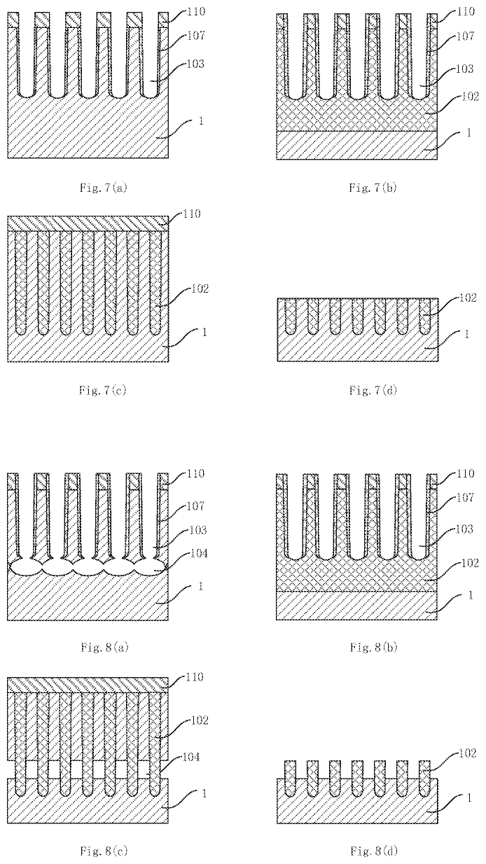

Referring to FIG. 7, in some embodiments of the present disclosure, sidewall oxide layers 107 may be formed on side walls of the second isolation trenches 103 before forming the bit lines.

FIG. 7(a) shows a schematic cross-sectional structural diagram of a structure obtained in the aa′ direction after the sidewall oxide layers 107 are formed, FIG. 7(b) shows a schematic cross-sectional structural diagram of the structure obtained in the bb′ direction after the sidewall oxide layers 107 are formed, FIG. 7(c) shows a schematic cross-sectional structural diagram of the structure obtained in the cc′ direction after the sidewall oxide layers 107 are formed, and FIG. 7(d) shows a schematic cross-sectional structural diagram of the structure obtained in the dd′ direction after the sidewall oxide layers 107 are formed.

According to an embodiment of the present disclosure, the bit lines may be formed in the substrate 1 by means of, for example, following steps.

First, the substrate 1 is etched based on the second isolation trenches 103, to form a plurality of bit line shallow trench isolation spaces (BL STI Spaces) 104 arranged at intervals below the active pillars 10, where the BL STI Spaces 104 all extend along the first direction.

As shown in FIG. 8, FIG. 8(a) shows a schematic cross-sectional structural diagram of a structure obtained in the aa′ direction after the BL STI Spaces 104 are formed, FIG. 8(b) shows a schematic cross-sectional structural diagram of the structure obtained in the bb′ direction after the BL STI Spaces 104 are formed, FIG. 8(c) shows a schematic cross-sectional structural diagram of the structure obtained in the cc′ direction after the BL STI Spaces 104 are formed, and FIG. 8(d) shows a schematic cross-sectional structural diagram of the structure obtained in the dd′ direction after the BL STI Spaces 104 are formed.

After the BL STI Spaces 104 are formed, bit lines are formed in the BL STI Spaces 104.

In an embodiment of the present disclosure, the bit lines may be formed in the BL STI Spaces 104 by means of, for example, following steps.

First metal silicide layers 108 are formed in the BL STI Spaces 104.

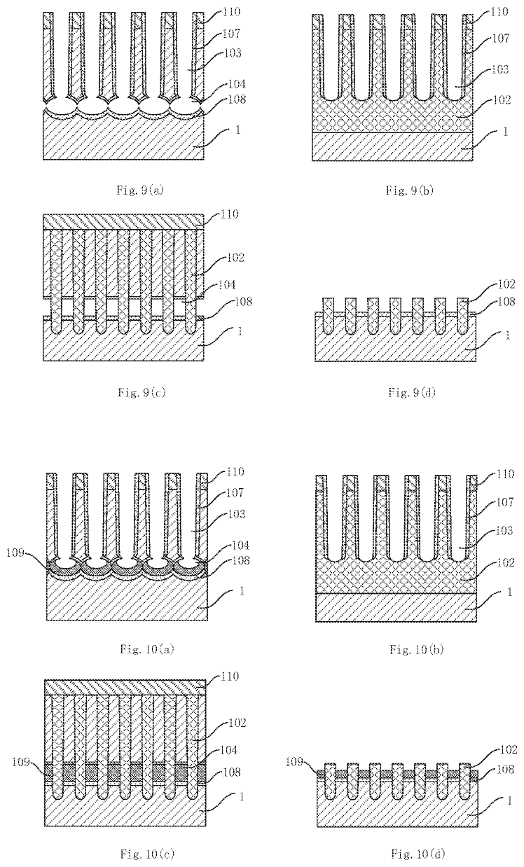

As shown in FIG. 9, FIG. 9(a) shows a schematic cross-sectional structural diagram of a structure obtained in the aa′ direction after the first metal silicide layers 108 are formed, FIG. 9(b) shows a schematic cross-sectional structural diagram of the structure obtained in the bb′ direction after the first metal silicide layers 108 are formed, FIG. 9(c) shows a schematic cross-sectional structural diagram of the structure obtained in the cc′ direction after the first metal silicide layers 108 are formed, and FIG. 9(d) shows a schematic cross-sectional structural diagram of the structure obtained in the dd′ direction after the first metal silicide layers 108 are formed.

The present disclosure does not limit manners of forming the first metal silicide layers 108. As an example, heat treatment, but not limited thereto, may be performed on the structure obtained, to form the first metal silicide layer 108 between the bit line and the substrate 1.

Referring to FIG. 10, bit lines 109 are formed on surfaces of the first metal silicide layers 108.

As shown in FIG. 10, FIG. 10(a) shows a schematic cross-sectional structural diagram of a structure obtained in the aa′ direction after the bit lines 109 are formed, FIG. 10(b) shows a schematic cross-sectional structural diagram of the structure obtained in the bb′ direction after the bit lines 109 are formed, FIG. 10(c) shows a schematic cross-sectional structural diagram of the structure obtained in the cc′ direction after the bit lines 109 are formed, and FIG. 10(d) shows a schematic cross-sectional structural diagram of the structure obtained in the dd′ direction after the bit lines 109 are formed.

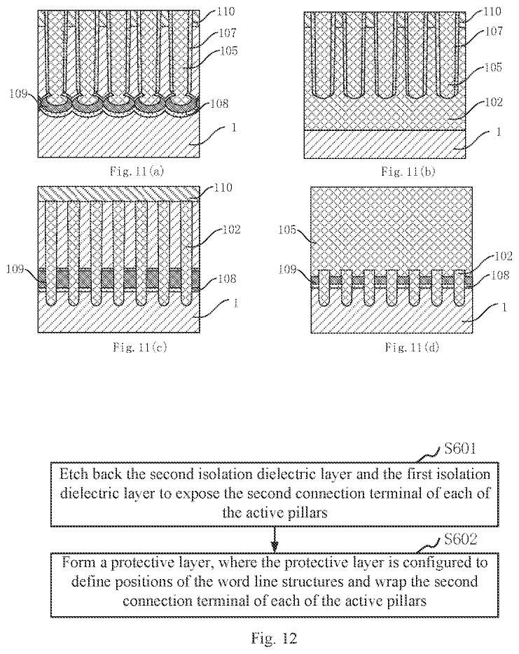

Referring to FIG. 11, in Step S5, a second isolation dielectric layer 105 is formed in the second isolation trench 103.

FIG. 11(a) shows a schematic cross-sectional structural diagram of a structure obtained in Step S5 in the aa′ direction, FIG. 11(b) shows a schematic cross-sectional structural diagram of the structure obtained in Step S5 in the bb′ direction, FIG. 11(c) shows a schematic cross-sectional structural diagram of the structure obtained in Step S5 in the cc′ direction, and FIG. 11(d) shows a schematic cross-sectional structural diagram of the structure obtained in Step S5 in the dd′ direction.

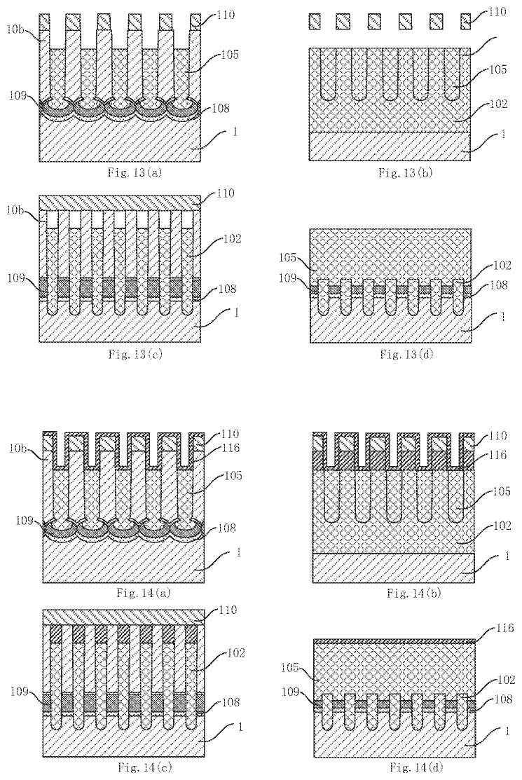

Referring to FIGS. 13 to 15 in conjunction with FIG. 12, in an embodiment of the present disclosure, Step S6 may include following steps.

S601: as shown in FIG. 13, etching back the second isolation dielectric layer 105 and the first isolation dielectric layer 102 to expose the second connection terminal 10b of each of the plurality of active pillars 10.

S602: as shown in FIGS. 14 to 15, forming a protective layer 106.

The protective layer 106 may be configured to define positions of the word line structures and wrap the second connection terminal 10b of each of the plurality of active pillars 10.

With continued reference to FIGS. 14 to 15, in an embodiment of the present disclosure, the protective layer 106 may be formed by means of, for example, following steps.

Patterned mask layers 110 extending along the first direction are formed on the top of the second connection terminal 10b. As shown in FIG. 14, FIG. 14(a) shows a schematic cross-sectional structural diagram of a structure obtained in the aa′ direction after the patterned mask layers 110 are formed, FIG. 14(b) shows a schematic cross-sectional structural diagram of the structure obtained in the bb′ direction after the patterned mask layers 110 are formed, FIG. 14(c) shows a schematic cross-sectional structural diagram of the structure obtained in the cc′ direction after the patterned mask layers 110 are formed, and FIG. 14(d) shows a schematic cross-sectional structural diagram of the structure obtained in the dd′ direction after the patterned mask layers 110 are formed. After the patterned mask layers 110 are formed, spacers 111 are formed on side walls of the second connection terminal 10b.

In some embodiments, the spacers 111 cover the second connection terminal 10b and the patterned mask layers 110, and fill up a spacing between the first isolation dielectric layer 102 and the patterned mask layer 110 and a spacing between the second isolation dielectric layer 105 and the patterned mask layer 110. As shown in FIG. 15, FIG. 15(a) shows a schematic cross-sectional structural diagram of a structure obtained in the aa′ direction after the spacers 111 are formed, FIG. 15(b) shows a schematic cross-sectional structural diagram of the structure obtained in the bb′ direction after the spacers 111 are formed, FIG. 15(c) shows a schematic cross-sectional structural diagram of the structure obtained in the cc′ direction after the spacers 111 are formed, and FIG. 15(d) shows a schematic cross-sectional structural diagram of the structure obtained in the dd′ direction after the spacers 111 are formed.

In the method for fabricating the semiconductor structure provided in the above embodiments, the sources/drains formed subsequently are protected by wrapping the second connection terminals 10b and the patterned mask layers 110. Moreover, the spacers 111 also fill up the spacings between first isolation dielectric layers 102 and the patterned mask layers 110 and the spacings between second isolation dielectric layers 105 and the patterned mask layers 110, thereby facilitating performing the step of etchback in the subsequent process of forming the word line structures.

The present disclosure does not limit manners of forming the spacers 111. As an example, the spacers 111 may be formed by means of following steps, for example. Spacer material layers 116 wrapping the second connection terminals 10b and the patterned mask layers 110 are formed first, as shown in FIG. 14, At this moment, the spacer material layers 116 also cover tops of the patterned mask layers 110. Next, part of the spacer material layers 116 at the tops of the patterned mask layers 110 are removed, as shown in FIG. 15, remaining part of the spacer material layers 116 serve as the spacers 111.

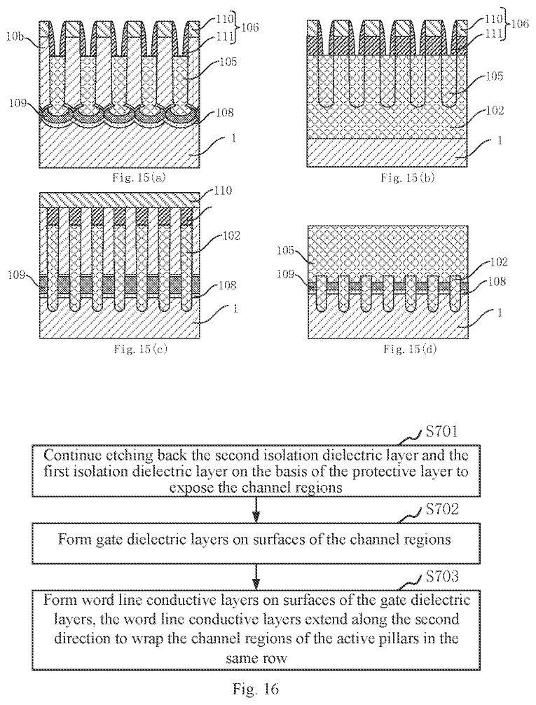

Referring to FIG. 16, in an embodiment of the present disclosure, after the protective layer 106 is formed, the method for fabricating the semiconductor structure may further include following steps.

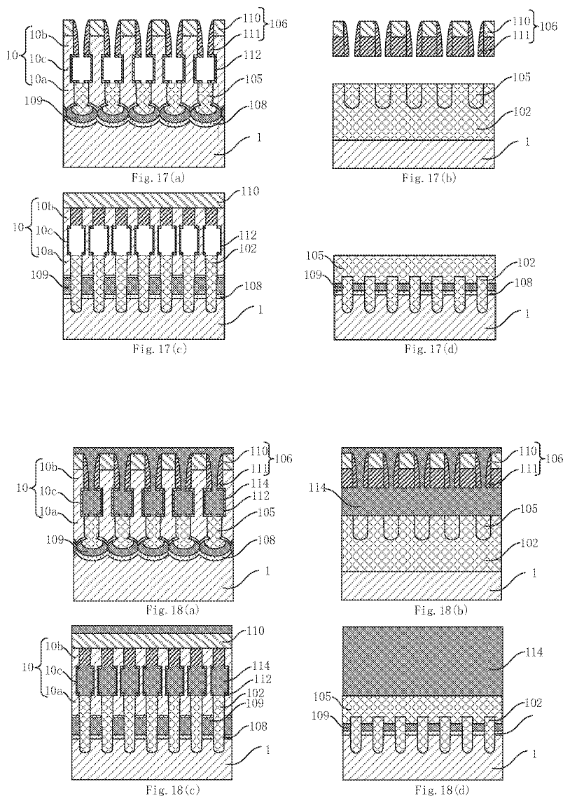

S701: as shown in FIG. 17, continuing etching back the second isolation dielectric layer 105 and the first isolation dielectric layer 102 on the basis of the protective layer 106 to expose the channel regions 10c.

S702: as shown in FIG. 17, forming gate dielectric layers 112 on surfaces of the channel regions 10c, where the gate dielectric layers 112 are configured to wrap the channel regions 10c.

FIG. 17(a) shows a schematic cross-sectional structural diagram of a structure obtained in Step S702 in the aa′ direction, FIG. 17(b) shows a schematic cross-sectional structural diagram of the structure obtained in Step S702 in the bb′ direction, FIG. 17(c) shows a schematic cross-sectional structural diagram of the structure obtained in Step S702 in the cc′ direction, and FIG. 17(d) shows a schematic cross-sectional structural diagram of the structure obtained in Step S702 in the dd′ direction.

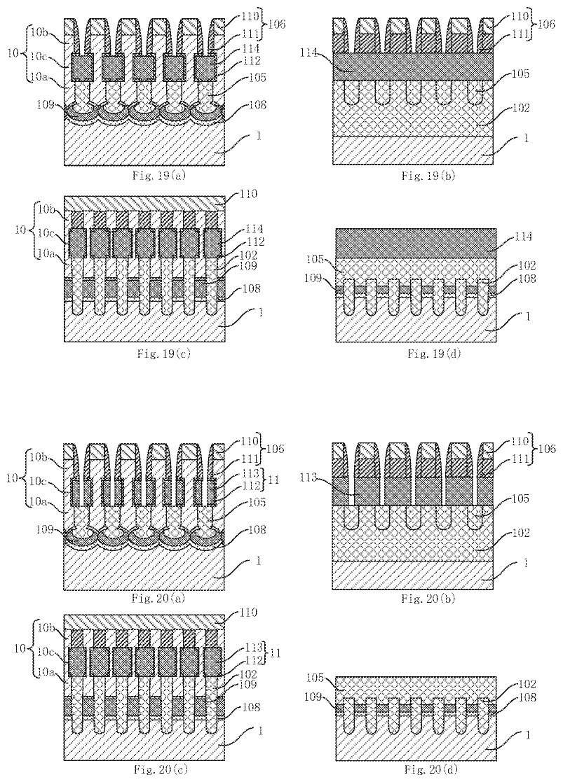

S703: as shown in FIG. 18 to FIG. 19, forming word line conductive layers 113 on surfaces of the gate dielectric layers 112.

In some embodiments, the word line conductive layers 113 may extend along the second direction to wrap the channel regions 10c of the active pillars 10 in the same row.

It is to be understood that, in this embodiment of the present disclosure, the word line structure 11 may include a gate dielectric layer 112 and a word line conductive layer 113.

With continued reference to FIG. 18 to FIG. 19. in an embodiment of the present disclosure, the word line conductive layer 113 may be formed, for example, in the following manners.

Word line conductive material layers 114 are formed on the surface of the gate dielectric layer 112. At this moment, surfaces of the word line conductive material layers 114 away from the bit lines 109 may be higher than the second connection terminals 10b. As shown in FIG. 18, FIG. 18(a) shows a schematic cross-sectional structural diagram of a structure obtained in the aa′ direction after the word line conductive material layers 114 are formed, FIG. 18(b) shows a schematic cross-sectional structural diagram of the structure obtained in the bb′ direction after the word line conductive material layers 114 are formed, FIG. 18(c) shows a schematic cross-sectional structural diagram of the structure obtained in the cc′ direction after the word line conductive material layers 114 are formed, and FIG. 18(d) shows a schematic cross-sectional structural diagram of the structure obtained in the dd′ direction after the word line conductive material layers 114 are formed. After the word line conductive material layers 114 are formed, the word line conductive material layers 114 are etched back for the first time, such that the surfaces of the word line conductive material layers 114 away from the bit lines 109 are flush with the channel regions 10c and the second connection terminals 10b. As shown in FIG. 19, FIG. 19(a) shows a schematic cross-sectional structural diagram of a structure obtained in the aa′ direction after performing first etchback on the word line conductive material layers 114, FIG. 19(b) shows a schematic cross-sectional structural diagram of the structure obtained in the bb′ direction after performing the first etchback on the word line conductive material layers 114, FIG. 19(c) shows a schematic cross-sectional structural diagram of the structure obtained in the cc′ direction after performing the first etchback on the word line conductive material layers 114, and FIG. 19(d) shows a schematic cross-sectional structural diagram of the structure obtained in the dd′ direction after performing the first etchback on the word line conductive material layers 114. After the word line conductive material layers 114 are etched back for the first time, it is continued to etch back the word line conductive material layers 114 until remaining part of the word line conductive material layers 114 cover the channel regions 10c of the active pillars 10 in the same row. In this case, the remaining part of the word line conductive material layers 114 are used as the word line conductive layers 113. As shown in FIG. 20, FIG. 20(a) shows a schematic cross-sectional structural diagram of a structure obtained in the aa′ direction after the word line conductive layers 113 are formed, FIG. 20(b) shows a schematic cross-sectional structural diagram of the structure obtained in the bb′ direction after the word line conductive layers 113 are formed, FIG. 20(c) shows a schematic cross-sectional structural diagram of the structure obtained in the cc′ direction after the word line conductive layers 113 are formed, and FIG. 20(d) shows a schematic cross-sectional structural diagram of the structure obtained in the dd′ direction after the word line conductive layers 113 are formed.

Referring to FIG. 21, in an embodiment of the present disclosure, filling dielectric layers 115 may be formed after the word line structures 11 are formed.

As shown in FIG. 21, FIG. 21(a) shows a schematic cross-sectional structural diagram of a structure obtained in the aa′ direction after the filling dielectric layers 115 are formed, FIG. 21(b) shows a schematic cross-sectional structural diagram of the structure obtained in the bb′ direction after the filling dielectric layers 115 are formed, FIG. 21(c) shows a schematic cross-sectional structural diagram of the structure obtained in the cc′ direction after the filling dielectric layers 115 are formed, and FIG. 21(d) shows a schematic cross-sectional structural diagram of the structure obtained in the dd′ direction after the filling dielectric layers 115 are formed. In some embodiments, the filling dielectric layers 115 are positioned on the upper surfaces of the remaining part of the first isolation dielectric layers 102 and the upper surfaces of the remaining part of the second isolation dielectric layers 105, and the filling dielectric layers 115 are configured to fill up spacings between adjacent word line structures 11.

It is to be understood that although the various steps in the flowcharts of FIG. 1, FIG. 12 and FIG. 16 are displayed in sequence as indicated by the arrows, these steps are not necessarily performed in sequence in the order indicated by the arrows. Unless expressly stated herein, the execution of these steps is not strictly restrictive and may be performed in other order. Moreover, at least some of the steps in FIG. 1, FIG. 12 and FIG. 16 may include a plurality of steps or a plurality of phases, which are not necessarily executed at the same moment, but may be executed at different moments, and the order of execution of these steps or phases is not necessarily performed sequentially, but may be executed alternately or alternately with other steps or at least a portion of steps or phases in the other steps.

According to some embodiments, the present disclosure also provides a semiconductor structure.

With continued reference to FIG. 21, in one embodiment, the semiconductor structure may include a substrate 1, a first isolation dielectric layer 102, a second isolation dielectric layer 105, a plurality of word line structures 11 arranged at intervals, and a protective layer 106.

The substrate 1 may have a first isolation trench 101 and a second isolation trench 103 therein. The first isolation trench 101 and the second isolation trench 103 isolate a plurality of active pillars 10 arranged at intervals. The first isolation trench 101 extends along a first direction, the second isolation trench 103 extends along a second direction, and the first direction intersects with the second direction. A width of the second isolation trench 103 should be greater than that of the first isolation trench 101. Each of the active pillars 10 includes a first connection terminal, a second connection terminal 10b, and a channel region 10c between the first connection terminal and the second connection terminal 10b.

The first isolation dielectric layer 102 is positioned in the first isolation trench 101, and the second isolation dielectric layer 105 is positioned in the second isolation trench 103. The second isolation dielectric layer 105 and the first isolation dielectric layer 102 jointly wrap the first connection terminal of each active pillar 10, and the second isolation dielectric layer 105 and the first isolation dielectric layer 102 expose the second connection terminal 10b.

Each of the word line structures 11 extends along the second direction to wrap the channel regions 10c of the active pillars 10 in the same row.

The protective layer 106 surrounds the second connection terminal 10b of each active pillar 10.

The semiconductor structure in the above embodiment has the second isolation trenches wider than the first isolation trenches, and such a structure can provide larger space for the subsequent formation of the word line structures 11. Furthermore, the sources/drains formed subsequently may also be protected.

With continued reference to FIG. 21, in one embodiment, the semiconductor structure may further include a plurality of bit lines 109 arranged at intervals.

The bit lines 109 are positioned below the active pillars 10, and all the bit lines 109 extend along the first direction, to sequentially connect in series the first connection terminals of the active pillars 10 in the same column.

With continued reference to FIG. 21, in one embodiment, the word line structure 11 may include a gate dielectric layer 112 and a word line conductive layer 113.

The gate dielectric layer 112 is positioned on the surface of the channel region 10c and wraps the channel region 10c.

The word line conductive layer 113 is positioned on the surface of the gate dielectric layer 112, extends along the second direction, and wraps the channel regions 10c of the active pillars 10 in the same row.

With continued reference to FIG. 21, in one embodiment, the protective layer 106 may include a patterned mask layer 110.

The patterned mask layer 110 may be positioned on the top of the second connection terminal 10b and extend along the first direction.

With continued reference to FIG. 21, in one embodiment, the protective layer 106 may further include spacers 111.

The spacers 111 may be positioned on side walls of the second connection terminal 10b to wrap the second connection terminal 10b and the patterned mask layer 110. Furthermore, the spacers 111 can fill up spacings between the first isolation dielectric layer 102 and the patterned mask layer 110 and spacings between the second isolation dielectric layer 105 and the patterned mask layer 110.

With continued reference to FIG. 21, in one embodiment, the semiconductor structure may further include a filling dielectric layer 115.

The filling dielectric layer 115 may be positioned on the upper surface of the first isolation dielectric layer 102 and the upper surface of the second isolation dielectric layer 105, and fill up spacings between adjacent word line structures 11.

According to some embodiments, the present disclosure also provides a method for fabricating the storage structure.

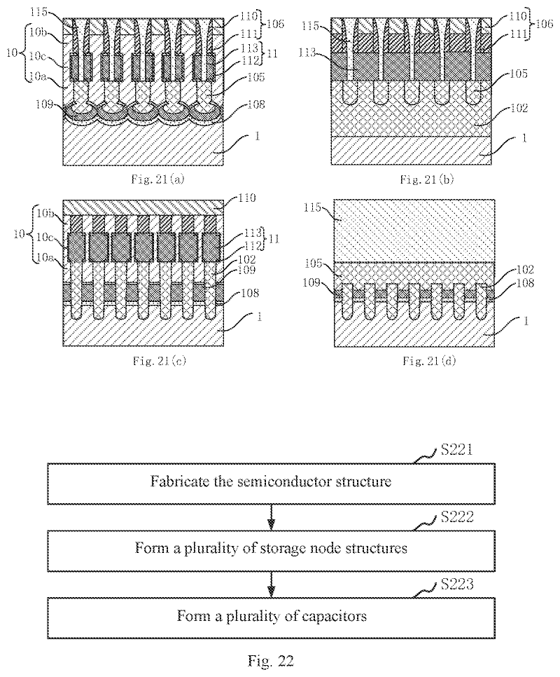

Referring to FIG. 22, in one embodiment, the method for fabricating the storage structure may include following steps.

S221: fabricating a semiconductor structure by means of the method for fabricating a semiconductor structure provided in any one of the foregoing embodiments.

S222: forming a plurality of storage node structures. The storage node structures may be positioned above the second connection terminals 10b of the active pillars 10, and are connected in one-to-one correspondence to the second connection terminals 10b.

S223: forming a plurality of capacitors. The capacitors may be positioned on upper surfaces of the storage node structures, and are arranged in one-to-one correspondence with the storage node structures.

The method for fabricating the storage structure provided by the present disclosure includes the semiconductor structure fabricated by means of the method for fabricating the semiconductor structure provided in the foregoing embodiments. Therefore, technical effects that can be achieved by the above method for fabricating the semiconductor structure can also be achieved by the method for fabricating the storage structure, which is not described in detail herein.

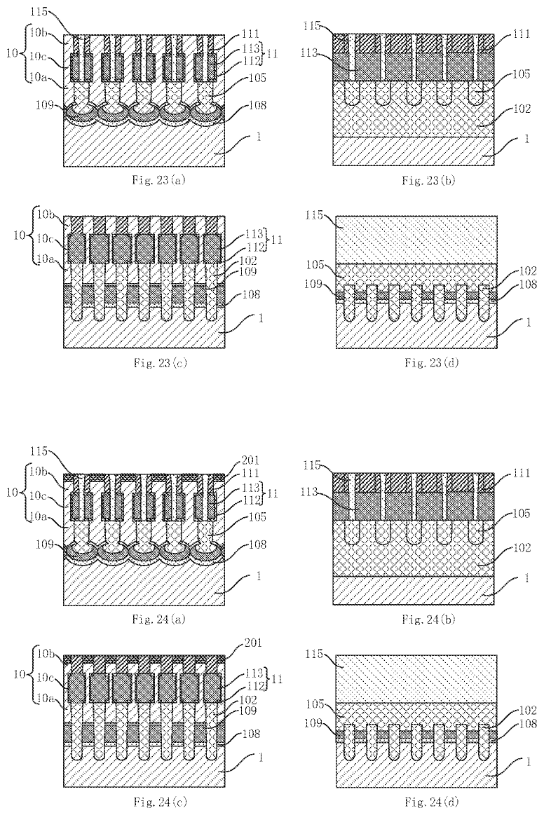

As described above, in some possible embodiments of the present disclosure, the patterned mask layers 110 extending along the first direction are formed at the tops of the second connection terminals 10b. Referring to FIG. 23 on this basis, in the method for fabricating the storage structure provided by one of the embodiments, a step of removing the patterned mask layers 110 may be further included before Step S221.

The present disclosure does not limit a manner of removing the patterned mask layers 110. As an example, the patterned mask layers 110 may be removed by means of, but not limited to, a chemical-mechanical polishing (CMP) process.

Referring to FIG. 24, in one embodiment, after the semiconductor structure is formed, and before storage node structures are formed, the method for fabricating the storage structure may further include a step of forming metal silicide layers 201 on the upper surfaces of the second connection terminals 10b of the active pillars 10.

On the basis of the above embodiments, the storage node structures may be formed on the upper surfaces of the metal silicide layers 201.

It should be noted that, the above step of forming the metal silicide layers 201 may be performed after the patterned mask layers 110 are removed.

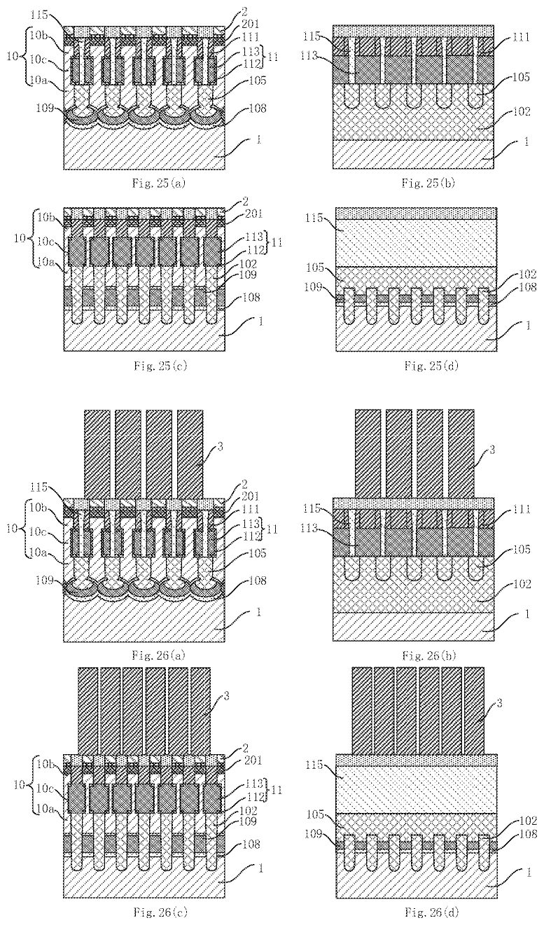

Referring to FIG. 25, in Step S222, a plurality of storage node structures 2 are formed.

The storage node structures 2 are positioned above the second connection terminals 10b of the active pillars 10, and are connected in one-to-one correspondence to the second connection terminals 10b.

Referring to FIG. 26, in Step S223, a plurality of capacitors 3 are formed.

The capacitors 3 are positioned on the upper surfaces of the storage node structures 2, and are arranged in one-to-one correspondence with the storage node structures 2.

According to some embodiments, the present disclosure also provides a storage structure.

With continued reference to FIG. 26, in one embodiment, the storage structure may include the semiconductor structure, the plurality of storage node structures 2 and the plurality of capacitors 3 as provided in any one of the above embodiments.

The storage node structures 2 are positioned above the second connection terminals 10b of the active pillars 10, and are connected in one-to-one correspondence to the second connection terminals 10b. The capacitors 3 are positioned on the upper surfaces of the storage node structures 2, and are arranged in one-to-one correspondence with the storage node structures 2.

The storage structure provided by the present disclosure includes the semiconductor structure provided in the above embodiments. Therefore, the technical effects that can be achieved by the above semiconductor structure can also be achieved by the storage structure, which is not described in detail herein.

With continued reference to FIG. 26, in one embodiment, the storage structure may further include metal silicide layers 201.

On the basis of the above embodiments, the storage node structures 2 may be formed on the upper surfaces of the metal silicide layers 201.

It should be noted that, the methods for fabricating the semiconductor structures in the embodiments of the present disclosure may be configured to fabricate the corresponding semiconductor structures. Therefore, technical features between the method embodiments and the structure embodiments may be replaced and supplemented with each other on the premise of no conflict, such that those skilled in the art can learn technical contents of the present disclosure.

The technical features of the above embodiments may be arbitrarily combined. For simplicity, all possible combinations of the technical features in the above embodiments are not described. However, as long as the combination of these technical features is not contradictory, it shall be deemed to be within the scope recorded in this specification.

The above embodiments merely express a plurality of implementations of the present disclosure, and descriptions thereof are relatively concrete and detailed. However, these embodiments are not thus construed as limiting the patent scope of the present disclosure. It is to be pointed out that for persons of ordinary skill in the art, some modifications and improvements may be made under the premise of not departing from a conception of the present disclosure, which shall be regarded as falling within the scope of protection of the present disclosure. Thus, the scope of protection of the present disclosure shall be subject to the appended claims.

What is claimed is:

1. A method for fabricating a semiconductor structure, comprising:
providing a substrate;
etching the substrate to form a first isolation trench in the substrate, the first isolation trench extending along a first direction;
filling a first isolation dielectric layer in the first isolation trench;
etching the substrate and the first isolation dielectric layer to form a second isolation trench, the second isolation trench extending along a second direction, the first direction intersecting with the second direction, the second isolation trench and the first isolation trench being configured to jointly isolate a plurality of active pillars, a width of the second isolation trench being greater than a width of the first isolation trench, and each of the plurality of active pillars comprising a first connection terminal, a second connection terminal, and a channel region positioned between the first connection terminal and the second connection terminal;
forming a second isolation dielectric layer in the second isolation trench;
forming a plurality of word line structures arranged at intervals, the plurality of word line structures all extending along the second direction to wrap the channel regions of the plurality of active pillars positioned in a same row;
etching back the second isolation dielectric layer and the first isolation dielectric layer to expose the second connection terminal of each of the plurality of active pillars; and
forming a protective layer, the protective layer being configured to define positions of the plurality of word line structures and wrap the second connection terminal of each of the plurality of active pillars.

2. The method for fabricating the semiconductor structure according to claim 1, wherein before forming the second isolation dielectric layer in the second isolation trench, the method for fabricating the semiconductor structure further comprises:
forming a plurality of bit lines arranged at intervals in the substrate, the plurality of bit lines being positioned below the plurality of active pillars, and the plurality of bit lines all extending along the first direction, to sequentially connect in series the first connection terminals of the plurality of active pillars positioned in a same column.

3. The method for fabricating the semiconductor structure according to claim 1, wherein a width of the second isolation trench is 1.2 times to 1.8 times a width of the first isolation trench.

4. The method for fabricating the semiconductor structure according to claim 1, wherein in a process of forming the plurality of word line structures, after forming the protective layer, the method for fabricating the semiconductor structure further comprises:
continuing etching back the second isolation dielectric layer and the first isolation dielectric layer on a basis of the protective layer to expose the channel regions;
forming gate dielectric layers on surfaces of the channel regions, the gate dielectric layers being configured to wrap the channel regions; and
forming word line conductive layers on surfaces of the gate dielectric layers, the word line conductive layers extending along the second direction to wrap the channel regions of the plurality of active pillars in the same row.

5. The method for fabricating the semiconductor structure according to claim 1, wherein the forming the protective layer comprises:
forming a patterned mask layer at a top of each of the second connection terminals, the patterned mask layer extending along the first direction.

6. The method for fabricating the semiconductor structure according to claim 5, wherein after forming the patterned mask layer, the method for fabricating the semiconductor structure further comprises:
forming spacers on side walls of the second connection terminals, the spacers being configured to wrap the second connection terminals and the patterned mask layer, and fill up a spacing between the first isolation dielectric layer and the patterned mask layer and a spacing between the second isolation dielectric layer and the patterned mask layer.

7. The method for fabricating the semiconductor structure according to claim 1, wherein after forming the plurality of word line structures, the method for fabricating the semiconductor structure further comprises:
forming a filling dielectric layer, the filling dielectric layer being positioned on an upper surface of a remaining part of the first isolation dielectric layer and an upper surface of a remaining part of the second isolation dielectric layer, and the filling dielectric layer being configured to fill up a spacing between adjacent two of the plurality of word line structures.

8. A semiconductor structure, comprising:
a substrate, the substrate being internally provided with a first isolation trench and a second isolation trench, the first isolation trench and the second isolation trench being configured to isolate a plurality of active pillars arranged at intervals, the first isolation trench extending along a first direction, the second isolation trench extending along a second direction, the first direction intersecting with the second direction, a width of the second isolation trench being greater than a width of the first isolation trench, and each of the plurality of active pillars comprising a first connection terminal, a second connection terminal, and a channel region positioned between the first connection terminal and the second connection terminal;
a first isolation dielectric layer positioned in the first isolation trench;
a second isolation dielectric layer positioned in the second isolation trench, the second isolation dielectric layer and the first isolation dielectric layer being configured to jointly wrap the first connection terminal of each of the plurality of active pillars, and the second isolation dielectric layer and the first isolation dielectric layer exposing the second connection terminal;
a plurality of word line structures arranged at intervals, the plurality of word line structures all extending along the second direction to wrap the channel regions of the plurality of active pillars positioned in a same row; and
a protective layer, the protective layer surrounding the second connection terminal of each of the plurality of active pillars.

9. The semiconductor structure according to claim 8, wherein the semiconductor structure further comprises:
a plurality of bit lines arranged at intervals, the plurality of bit lines being positioned below the plurality of active pillars, the plurality of bit lines all extending along the first direction to sequentially connect in series the first connection terminals of the plurality of active pillars positioned in a same column.

10. The semiconductor structure according to claim 8, wherein a width of the second isolation trench is 1.2 times to 1.8 times a width of the first isolation trench.

11. The semiconductor structure according to claim 8, wherein the plurality of word line structures comprise:
gate dielectric layers, positioned on surfaces of the channel regions and configured to wrap the channel regions; and
word line conductive layers positioned on surfaces of the gate dielectric layers and extending along the second direction, the word line conductive layers being configured to wrap the channel regions of the plurality of active pillars positioned in the same row.

12. The semiconductor structure according to claim 8, wherein the protective layer comprises a patterned mask layer,
the patterned mask layer being positioned at a top of each of the second connection terminals and extending along the first direction.

13. The semiconductor structure according to claim 12, wherein the protective layer further comprises spacers,
the spacers being positioned on side walls of the second connection terminals, and the spacers being configured to wrap the second connection terminals and the patterned mask layer, and fill up a spacing between the first isolation dielectric layer and the patterned mask layer and a spacing between the second isolation dielectric layer and the patterned mask layer.

14. The semiconductor structure according to claim 8, wherein the semiconductor structure further comprises:
a filling dielectric layer, the filling dielectric layer being positioned on an upper surface of the first isolation dielectric layer and an upper surface of the second isolation dielectric layer, and the filling dielectric layer being configured to fill up a spacing between adjacent two of the plurality of word line structures.

15. A method for fabricating a storage structure, comprising:
fabricating the semiconductor structure by means of the method for fabricating the semiconductor structure according to claim 1;
forming a plurality of storage node structures, the plurality of storage node structures being positioned above the second connection terminals of the plurality of active pillars, and being connected in one-to-one correspondence to the second connection terminals; and
forming a plurality of capacitors, the plurality of capacitors being positioned on upper surfaces of the plurality of storage node structures, and being arranged in one-to-one correspondence with the plurality of storage node structures.

16. The method for fabricating the storage structure according to claim 15, wherein after forming the semiconductor structure, and before forming the plurality of storage node structures, the method for fabricating the storage structure further comprises:
forming metal silicide layers on upper surfaces of the second connection terminals of the plurality of active pillars, the plurality of storage node structures being formed on upper surfaces of the metal silicide layers.

17. A storage structure, comprising:
the semiconductor structure according to claim 8;
a plurality of storage node structures, the plurality of storage node structures being positioned above the second connection terminals of the plurality of active pillars, and being connected in one-to-one correspondence to the second connection terminals; and
a plurality of capacitors, the plurality of capacitors being positioned on upper surfaces of the plurality of storage node structures, and being arranged in one-to-one correspondence with the plurality of storage node structures.
